(19) United States
(12) Patent Application Publication
(10) Pub. No.: US 2023/0014240 A1
(43) Pub. Date: Jan. 19, 2023

(54) FLIP-CHIP SEMICONDUCTOR LIGHT-EMITTING ELEMENT AND SEMICONDUCTOR LIGHT-EMITTING DEVICE

(71) Applicant: Xiamen San'an Optoelectronics Co., Ltd., Xiamen (CN)

(72) Inventors: MIN HUANG, Xiamen (CN); ZHANGGEN XIA, Xiamen (CN); YU ZHAN, Xiamen (CN); SU-HUI LIN, Xiamen (CN); ANHE HE, Xiamen (CN); CHUNG-YING CHANG, Xiamen (CN)

(21) Appl. No.: 17/864,394

(22) Filed: Jul. 14, 2022

(30) Foreign Application Priority Data
Jul. 16, 2021 (CN) 2021108044101

(51) Int. Cl. H01L 33/38; H01L 33/62; H01L 33/10

(52) U.S. Cl. CPC H01L 33/382; H01L 33/62; H01L 33/10

(57) ABSTRACT

A flip-chip semiconductor light-emitting element and a semiconductor light-emitting device are provided. The element includes a substrate and a light-emitting epitaxial layer disposed on the substrate. When electrode structures are formed overlying the light-emitting epitaxial layer, a first electrode layer partially covering the light-emitting epitaxial layer is omitted, thus a surface of the light-emitting epitaxial layer has a higher flatness. When an insulating reflective layer and an insulating protective layer are subsequently formed, flatness of the insulating reflective layer and the insulating protective layer can be ensured. An overall thickness of the insulating reflective layer and the insulating protective layer is no greater than 3 μm, no abnormal protrusions occur when electrode through holes are formed in the insulating reflective layer and the insulating protective layer, the electrode pads do not have cracks, fractures, and other defects, thus stability and reliability of the device can be enhanced.

### TECHNICAL FIELD

The disclosure relates to a field of semiconductor devices, in particularly to a flip-chip semiconductor light-emitting element and a semiconductor light-emitting device.

### BACKGROUND

A semiconductor light-emitting element, namely a light-emitting diode (LED), is widely used in large backlight units, general lighting, electrical components, and other products. A submillimeter LED (also referred to as mini-LED) is especially popular in a field of display panel because of its small size, high light source utilization and long service life.

With a size of the mini-LED continues to shrink, a design of chip graphics has higher and stricter requirements for a line width. At present, in a manufacturing process of the mini-LED, a first electrode layer is formed above an epitaxial layer, the first electrode layer does not completely cover the epitaxial layer, and a similar step structure is formed above the epitaxial layer. When an insulating reflective layer is formed, the insulating reflective layer has a corner above the step structure, which makes a surface of the insulating reflective layer uneven. When electrode pads are formed, the electrode pads also have uneven surface, which makes coverage of the electrode pads poor and has a risk of fracture of the electrode pads, in addition, in a process of die bonding, it will cause a poor die bonding and a hidden danger of fracture of the electrode pads, which will affect a reliability of a device.

As illustrated in FIG. 1A, in an existing mini-LED chip, a light-emitting epitaxial layer 020 is formed overlying a substrate 010, and the light-emitting epitaxial layer is provided with a mesa to expose a first semiconductor layer 021. An active layer 022 adjacent to the mesa is a light-emitting region, a transparent conductive layer 030 is formed overlying a second semiconductor layer 023, and a first electrode layer 040 including two portions, and the two portions of the first electrode layer 040 are respectively formed overlying the transparent conductive layer 030 and the first semiconductor layer 021 at the mesa. After the two portions of the first electrode layer 040 is formed, an insulating layer 050 covering the first electrode layer 040, the transparent conductive layer and the mesa is formed, openings (also referred to as electrode through holes) are defined at positions of the insulating layer corresponding to the first electrode layer 040, and a first electrode 061 and a second electrode 062 are formed in the openings. As illustrated in FIG. 1B, since the first electrode layer 040 only covers a portion of the first semiconductor layer and a portion of the transparent conductive layer, there is an inclination angle between an edge of the first electrode layer and a surface of the transparent conductive layer, such as 38.3° as illustrated in FIG. 1B. When the insulating layer 050 is deposited, because the insulating layer has may sublayers with a total thickness greater than 3 micrometers, the existence of the inclination angles will make the insulating layer have corners and protrusions here. In addition, when the electrode through holes are formed in the insulating layer, there is an inclination angle between a side wall of the insulating layer and an upper surface of the first electrode layer, such as 66.7° as illustrated in FIG. 1B. When electrode pads are formed overlying the first electrode layer, the above corners, protrusions and the inclination angles of the side walls of the electrode through hole will make material coverage of the electrode pad poor, and there will be defects such as fracture or crack, which will reduce the reliability of the device. In addition, due to the corners and protrusions of the insulating layer, the electrode pads also have protrusions, resulting in uneven surface of the device. In a later process of die bonding, a height difference of the device surface will cause poor die bonding, which also leads to a risk of the fracture of the electrode pads and affects the reliability of the device.

Therefore, it is necessary to provide a structure for improving the coverage of the electrode pads.

In order to solve the above problems, it is necessary to provide a structure that can improve the coverage of the electrode pads disposed overlying the epitaxial layer.

### SUMMARY

In view of disadvantages of the prior art described above, purposes of the disclosure are to provide a flip-chip semiconductor light-emitting element, a semiconductor light-emitting device, and a display device. In a design of the semiconductor light-emitting element, a metal layer disposed overlying an epitaxial layer is omitted to keep a surface of the epitaxial layer flat, and a thickness of the insulating layer disposed overlying the epitaxial layer is controlled to be less than or equal to 3 μm, thereby to prevent abnormal protrusions of the insulating layer, improve the coverage of electrode pads, and improve the reliability of the device.

In order to realize the above purposes and other related purposes, the disclosure provides a flip-chip semiconductor light-emitting element, including:
a light-emitting epitaxial layer, including: a first conductive type semiconductor layer, an active layer and a second conductive type semiconductor layer sequentially stacked from bottom to top in that order, the light-emitting epitaxial layer being provided with a mesa, and the first conductive type semiconductor layer forming an upper surface of the mesa;
an insulating reflective layer, disposed overlying the light-emitting epitaxial layer and covering side walls of the light-emitting epitaxial layer on two sides of the mesa; and
electrode pads, including: a first electrode pad electrically connected to the first conductive type semiconductor layer and a second electrode pad electrically connected to the second conductive type semiconductor layer;
a thickness of the insulating reflective layer being in a range of 1 μm to 3 μm

The disclosure further provides a semiconductor light-emitting device, including: a circuit substrate; and the flip-chip semiconductor light-emitting element as above described, flip-chip mounted on the circuit substrate.

The disclosure further provides a display device, including the flip-chip semiconductor light-emitting elements as above described.

The flip-chip semiconductor light-emitting element, the semiconductor light-emitting device and the display device provided by the disclosure at least have the following beneficial technical effects:
the flip-chip semiconductor light-emitting element of the disclosure includes a substrate and the light-emitting epitaxial layer disposed on the substrate, when electrode structures is formed overlying the light-emitting epitaxial layer, a first electrode layer partially covering the light-emitting epitaxial layer and on the light-emitting epitaxial layer is omitted, thus a surface of the light-emitting epitaxial layer has a high flatness. When an insulating reflective layer and an insulating protective layer are subsequently formed, flatness of the insulating reflective layer and the insulating protective layer can be ensured. Moreover, in the disclosure, an overall thickness of the insulating reflective layer and the insulating protective layer is no greater than 3 when electrode through holes are formed in the insulating reflective layer and the insulating protective layer, abnormal protrusions will not occur due to the excessive thickness of the insulation protective layer, the electrode through holes have good morphology, and the adhesion of the electrode pads in the electrode through holes and on the insulating protective layer is enhanced, the electrode pads will not have defects such as cracks or fractures, thereby the stability and reliability of the device can be enhanced. In addition, in the prior art, the thickness of the insulating layer is too thick, in order to ensure a size of a bottom opening of the electrode through hole of the insulating reflective layer, an upper opening of the electrode through hole is too large, which may lead to a risk of electric leakage due to the portion of the insulating reflective layer near the side wall of the mesa is thin, or a risk of reduction of luminous area due to the mesa is too large, the disclosure can avoid the above risks.

### BRIEF DESCRIPTION OF THE DRAWINGS

FIG. 1A illustrates a schematic structural view of a mini-LED of the related art.

FIG. 1B illustrates an electronic scan view of a circle A in FIG. 1A of the related art.

FIG. 2A illustrates a schematic structural view of a semiconductor light-emitting element according to an embodiment 1 of the disclosure.

FIG. 2B illustrates a schematic structural view of a semiconductor light-emitting element according to the embodiment 1 of the disclosure

FIG. 3 illustrates a top view of the semiconductor light-emitting element illustrated in FIG. 2A.

FIG. 4 illustrates a schematic structural view of another semiconductor light-emitting element according to an embodiment 1 of the disclosure.

FIG. 5 illustrates a schematic structural view of another semiconductor light-emitting element according to an embodiment 1 of the disclosure.

FIG. 6 illustrates a schematic structural view of a still another semiconductor light-emitting element according to an embodiment 1 of the disclosure.

FIG. 7 illustrates a schematic structural view of a semiconductor light-emitting element according to an embodiment 2 of the disclosure.

FIG. 8 illustrates a schematic structural view of a semiconductor light-emitting element according to an embodiment 3 of the disclosure.

FIG. 9A illustrates a schematic structural view of a semiconductor light-emitting element according to an embodiment 4 of the disclosure.

FIG. 9B illustrates a schematic structural view of a semiconductor light-emitting element according to the embodiment 4 of the disclosure

FIG. 10 illustrates a schematic structural view of a semiconductor light-emitting device according to an embodiment 5 of the disclosure.

FIG. 11 illustrates a schematic structural view of a display device according to an embodiment 6 of the disclosure.

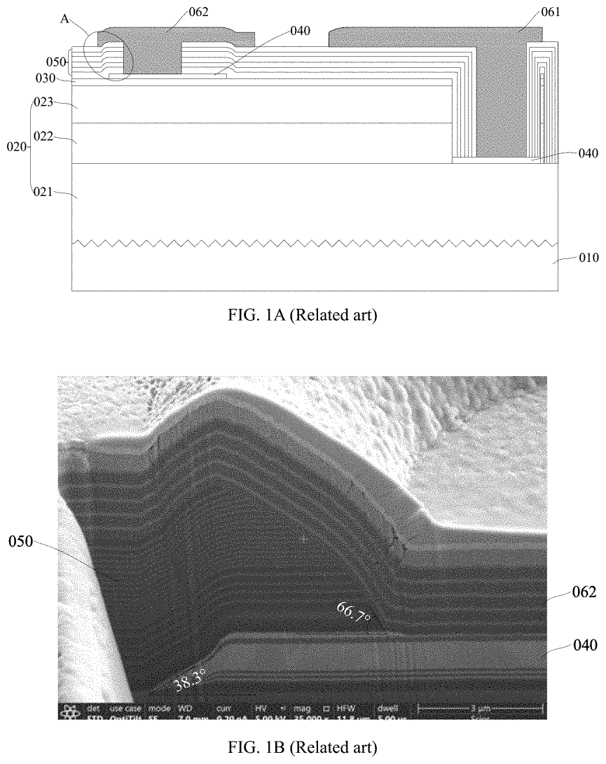

### DETAILED DESCRIPTION OF THE EMBODIMENTS

### Embodiment 1

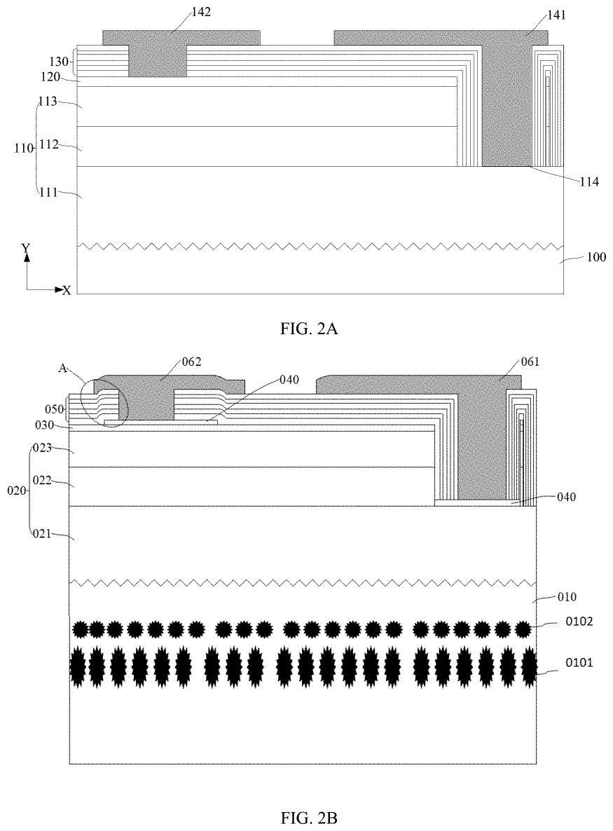

This embodiment provides a flip-chip semiconductor light-emitting element. As illustrated in FIG. 2A, the semiconductor light-emitting element of this embodiment includes a substrate 100 and a light-emitting epitaxial layer 110 disposed overlying the substrate 100. The light-emitting epitaxial layer 110 includes a first conductive type semiconductor layer 111, an active layer 112 and a second conductive type semiconductor layer 113 disposed on the substrate 100 from bottom to top in sequential order.

In this embodiment, the substrate 100 may be an insulating substrate. The substrate 100 may be a growth substrate for growing the light-emitting epitaxial layer 110, including, for example, a sapphire substrate. As illustrated in FIG. 2A, the substrate 100 further includes a plurality of projections formed on at least one area of an upper surface thereof. The plurality of projections of the substrate 100 may be formed into regular and/or irregular patterns. For example, the substrate 100 includes a patterned sapphire substrate (PSS).

In an optional embodiment, a thickness of the substrate 100 is no greater than 100 micro meters (μm), and a side wall of the substrate 100 has at least two cutting lines with different depths (which are not illustrated in FIG. 2A). Taking the two cutting lines including a first cutting line and a second cutting line as an example, the first cutting line is closer to a position corresponding to ½ of the thickness of the substrate than the second cutting line, and the second cutting line is closer to the light-emitting epitaxial layer than the first cutting line. Alternatively, a roughness of the first cutting line is higher than that of the second cutting line, or a burst point spacing of the first cutting line is smaller than that of the second cutting line.

The light-emitting epitaxial layer 110 is disposed on an upper surface of the substrate 100. As illustrated in FIG. 2A, in this embodiment, the light-emitting epitaxial layer is disposed overlying the plurality of projections of the upper surface of the substrate 100. The first conductive type semiconductor layer 111, the active layer 1112, and the second conductive type semiconductor layer 113 may respectively include III-V nitride semiconductors, for example, the nitride semiconductor may be a nitride semiconductor of one of aluminium (Al), gallium (Ga), and indium (In). The first conductive type semiconductor layer 111 may include a n-type dopant, such as, silicon (Si), germanium (Ge), or stannum (Sn). The second conductive type semiconductor layer 113 may include a p-type dopant, such as, magnesium (Mg), strontium (Sr), or barium (Ba). It is understood that the dopants of the first conductive type semiconductor layer and the second conductive type semiconductor layer may also be opposite to the above, i.e., the first conductive type semiconductor layer 111 may include the p-type dopant, and the second conductive type semiconductor layer 113 may include the n-type dopant. The active layer 112 may include a multiple quantum well (MQW) structure, and the active layer 112 may emit a desired wavelength by adjusting a composition ratio of the nitride semiconductor.

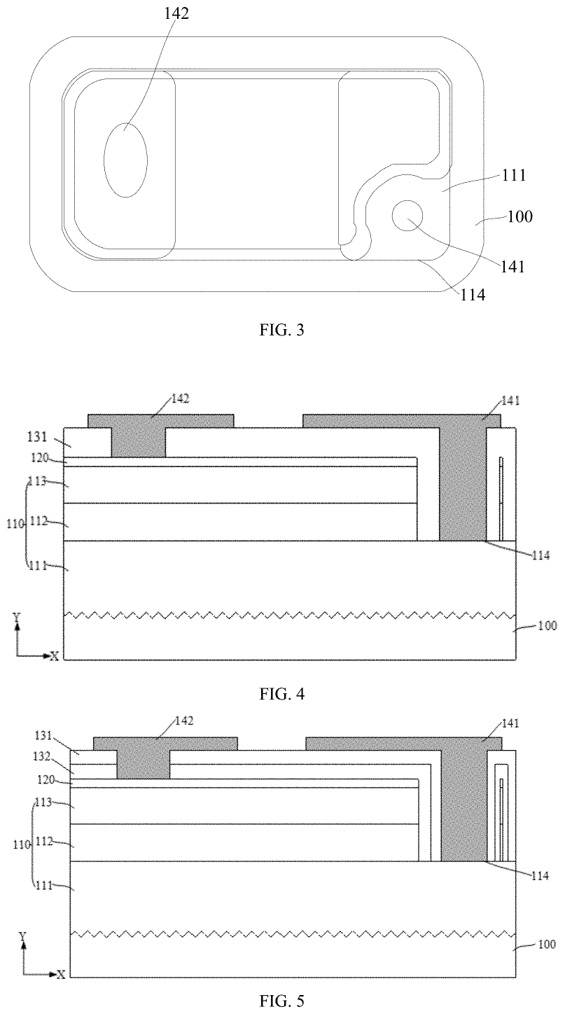

In this embodiment, the second conductive type semiconductor layer 113 may be a p-type semiconductor layer. Referring to FIGS. 2A and 3, the light-emitting epitaxial layer 110 is provided with a mesa 114 to expose the first conductive type semiconductor layer 111. The mesa is formed by etching the second conductive type semiconductor layer 113 and the active layer 112 until the first conductive type semiconductor layer 111 is exposed. Alternatively, after etching the second conductive type semiconductor layer 113 and the active layer 112, the first conductive type semiconductor layer 111 may be continuously etched to form the mesa 114. The mesa can be located in a middle region of the light-emitting epitaxial layer or in an edge region of the light-emitting epitaxial layer. As illustrated in FIG. 3, in this embodiment, the mesa 114 is formed in the edge region of the light-emitting epitaxial layer, which is conducive to reducing an area of the mesa and increasing a light-emitting area.

Referring to FIG. 2A, the semiconductor light-emitting element of this embodiment further includes an insulating layer 130 disposed overlying the second conductive type semiconductor layer 113, the first conductive type semiconductor layer 111 at the mesa 114 and covering side walls of the mesa 114. In this embodiment, an overall thickness of the insulating layer (i.e., insulating reflective layer and insulating protective layer) is no more than 3 μm. In an optional embodiment, the number of layers of the insulating layer is less than or equal to 5, and the insulating layer is a single layer or a stacked layer of different material layers, that is, the insulating layer does not include repeated stacked layers. The insulating layer can be a single-layer structure, such as a silicon oxide layer or a silicon nitride layer. When applied to a display screen, the thickness of the single-layer insulating layer is at least 300 nm. And preferably, the thickness of the single-layer insulating layer is no greater than 2500 nm. Or in order to ensure electro-static discharge (ESD) performance, the thickness is in a range of 500 nm to 1500 nm.

In an optional embodiment, the insulating layer 130 may also be a multilayer structure, as illustrated in FIG. 4, the insulating layer 130 may include an insulating reflective layer 131 disposed overlying the second conductive type semiconductor layer 113. The insulating reflective layer 131 includes a distributed Bragg reflector, which includes an insulating reflective layer formed by repeatedly stacking two dielectric layers with different refractive indices. The dielectric layer may be, for example, an oxide layer, such as titanium oxide, silicon oxide, hafnium oxide, magnesium fluoride, and the like. In some embodiments, the distributed Bragg reflector may be two insulating material layers that are repeatedly stacked, such as a silicon oxide layer and a titanium oxide layer that are alternately stacked, a first layer is the silicon oxide layer. Each layer of the distributed Bragg reflector may have an optical thickness of ¼ of a specific wavelength, and may form a stacked layer of 3 to 15 pairs of dielectric layers with two different refractive indices. The distributed Bragg reflective layer can be formed by an evaporation process, and the thickness of the formed insulating reflective layer is in a range of 1 μm to 3 μm.

In an optional embodiment of this embodiment, as illustrated in FIG. 5, the insulating layer 130 further includes a first insulating protective layer 132 formed between the insulating reflective layer 131 (i.e., the distributed Bragg reflector) and the light-emitting epitaxial layer 110, and a compactness of the first insulating protective layer 132 is higher than that of the insulating reflective layer 131. For example, the first insulating protective layer can be an aluminum oxide layer, which can be formed by atomic layer deposition method to ensure its compactness, so as to avoid water vapor entering the surface of the light-emitting epitaxial layer. Preferably, a thickness of the aluminum oxide layer is in a range of 50 nm to 200 nm. Or the first insulating protective layer 132 is a silicon oxide layer, which is obtained by a plasma enhanced chemical vapor deposition (PECVD) method. A thickness of the silicon oxide layer is in a range of 80 nm to 450 nm. Compared with the silicon oxide layer, the alumina layer has higher compactness.

In another optional embodiment of this embodiment, as illustrated in FIG. 6, the insulating layer 130 further includes a second insulating protective layer 133 formed overlying the insulating reflective layer 131, and a compactness of the second insulating protective layer 133 is higher than that of the insulating reflective layer 131. The second insulating protective layer 133 can be one of a silicon oxide layer and a silicon nitride layer, which can be formed by the PECVD. The second insulating protective layer 133 also has good moisture resistance and protects the light-emitting element from moisture. A thickness of the second insulating protective layer 133 is in a range of 8 nm to 50 nm. Preferably, the second insulating protective layer 133 disposed overlying the insulating reflective layer 131 can be an aluminum oxide layer, which is formed by an atomic layer deposition method. The aluminum oxide layer formed by the atomic layer deposition method has higher compactness than the silicon oxide layer or silicon nitride layer. A thickness of the aluminum oxide layer forming the second insulating protective layer 133 is in a range of 8 nm to 200 nm. Preferably, the thickness of the second insulating protective layer 133 is lower than that of each insulating material layer in the insulating reflective layer 133, and an excessive thickness is not necessary.

Optionally, one of the second insulating protective layer 133 and the first insulating protective layer 132 can be selectively arranged on a side of the insulating reflective layer 131. Preferably, the first insulating protective layer 132 and the second insulating protective layer 133 are respectively arranged on two sides of the insulating reflective layer 131. Alternatively, as illustrated in FIG. 2A, a transparent conductive layer 120 is disposed between the second conductive type semiconductor layer 113 and the insulating layer 130. The transparent conductive layer 120 is disposed overlying the second conductive type semiconductor layer 113 and is in ohmic contact with the second conductive type semiconductor layer 113. The transparent conductive layer 120 may include at least one of a transparent conductive oxide such as indium tin oxide (ITO), zinc oxide (ZnO), zinc indium tin oxide (ZITO), zinc indium oxide (ZIO), zinc tin oxide (ZTO), gallium indium tin oxide (GITO), gallium indium oxide (GIO), gallium zinc oxide (GZO), and aluminum doped zinc oxide (AZO), fluorine doped tin oxide (FTO), and transparent metal layers such as Ni metal layer and Au metal layer. The conductive oxide may further include various dopants. In this embodiment, the transparent conductive layer 120 almost completely covers a surface of the second conductive type semiconductor layer 113, and the coverage area can reach more than 90%.

Referring to FIG. 2A and FIG. 3, the semiconductor light-emitting element further includes electrode pads, which include a first electrode pad 141 and a second electrode pad 142, the first electrode pad is electrically connected to the first conductive type semiconductor layer, and the second electrode pad is electrically connected to the second conductive type semiconductor layer to form an electrical connection. For example, the second electrode pad can be directly in contact with the second conductive type semiconductor layer to form an electrical connection.

When forming the above electrode pads, firstly, the insulating layer 130 disposed overlying the light-emitting epitaxial layer is etched, the first through hole (not shown in detail) is formed at the mesa 114, and the second through hole (not shown in detail) is formed overlying the transparent conductive layer 120. For example, the insulating protective layer can be etched by wet etching, and the insulating reflective layer can be etched by inductively couple plasma (ICP) etching. Side walls of the first through hole and the second through hole are inclined side walls, and an included angle between the side wall and a horizontal plane of the epitaxial layer (i.e., a X direction in FIG. 2A) is in a range of 15° to 60°. Then, the first electrode pad and the second electrode pad are formed by depositing a conductive material in the formed first through hole and the second through hole and on the upper surface of the insulating layer around the first through hole and the second through hole. The conductive material can be a metal material or an alloy material, such as one or more combinations of aurum (Au), argentum (Ag), Al, cuprum (Cu), platinum (Pt), titanium (Ti), and chromium (Cr). The first electrode pad and the second electrode pad are formed on the upper surface of the insulating layer, and filled in the first through hole and the second through hole respectively to contact the surface of the first conductive type semiconductor layer and the transparent conductive layer. Because the thickness of the insulating layer is small, it is conducive to the uniform deposition of the conductive material on the side wall of the through hole and the upper surface of the insulating layer around the through hole. The first electrode pad and the second electrode pad have good flatness, which is conducive to enhancing the reliability of the pad.

As an example, the first electrode pad includes at least an adhesive layer, a reflective layer and a eutectic layer sequentially stacked from bottom to top in that order. The adhesive layer is Cr or Ti, and used to adhesive the insulating layer, the reflective layer is Al, and the eutectic layer is Ni or Ni/Pt layer or Ni/Pt/Au layer or Ni/Sn layer. When the eutectic layer allows the semiconductor light-emitting element to be installed on the application substrate in a flip-chip manner, die bonding is formed by using solder paste and reflow soldering process, so as to realize the stable installation of the semiconductor light-emitting element on the application substrate, or when the eutectic layer itself has tin, the solder paste can be reduced or cancelled, and the die bonding can be formed after direct reflow soldering process. In an optional embodiment of this embodiment, as illustrated in FIG. 3, the first through hole can be circular, square or polygonal. In this embodiment, the first through hole is preferably formed as a through hole with a circular opening, and the second through hole can be formed as a through hole with a circular opening, square opening or polygonal opening, with a finger structure around. Since the thickness of the insulating layer is no more than 3 μm. Therefore, when forming the first through hole, the aperture of the first through hole can be controlled to be as small as possible, for example, the diameter of the first through hole can be made less than 12 μm. When the aperture of the first through hole is reduced, the area of the mesa occupied by the first through hole can be reduced correspondingly, and the distance from an edge the of mesa can be reduced. Therefore, the area of the mesa can also be reduced correspondingly, so that the area of the active layer in the semiconductor light-emitting element can be increased, that is, the light-emitting area of the light-emitting element can be increased, which is conducive to improving the light-emitting efficiency of the light-emitting element. In addition, since the current expansion of the P layer in the light-emitting element is much worse than that of the N layer, the smaller the area of the N layer, the larger the area of the P layer, which can balance the current expansion of the P layer and the N layer, so as to improve the ESD capability of the light-emitting element.

The light-emitting layer of the semiconductor light-emitting element of the disclosure can provide one of blue light, green light and red light-emitting radiation. The semiconductor light-emitting element of the disclosure is better suitable for light-emitting devices under low current density, such as LED display screens, such as indoor or outdoor display screens, in which the white light of the display screen is mixed by blue LED chips, red LED chips and green LED chips.

Preferably, when applied to the design of the display screen, at least one dimension of the chip of the flip-chip semiconductor light-emitting element is no more than 300 microns. When used in the design of the display screen, all the dimensions of the chip of the semiconductor light-emitting element are no more than 300 microns.

Preferably, when applied to the design of the display screen, the thickness of the substrate is no more than 100 microns, such as 100 microns or 80 microns or 60 microns.

To achieve a chip with symmetrical structure, the sidewall of the substrate extends perpendicular to the direction of the upper surface, so as to prevent the chip from skewing after being installed on the circuit substrate. The side wall of the substrate has at least two cutting lines with different depths formed by the laser hidden cutting technology. As the crack deviates from the cutting lines along thickness direction to the surface off the substrate, it will damage the epitaxial region of the chip, and resulting in leakage. The use of at least two cutting lines can to a certain extent prevent the substrate from diagonal cracking. For example, as illustrated in FIG. 2B, two cutting lines are formed on the sidewall of the substrate, the first cutting line 0101 is closer to the position of ½ thickness of the substrate than the second cutting line 0102, the first cutting line 0101 is located at the position of ±10 μm of the ½ thickness of the substrate, and the second cutting line 0102 is closer to the light-emitting epitaxial structure than the first cutting line 0101. Preferably, the two cutting lines are composed of multiple laser ablation formed explosive points. The roughness of the explosive point of the first cutting line 0101 is greater than that of the explosive point of the second cutting line 0102. The difference of the roughness is formed by controlling the laser intensity. Since the second cutting line 0102 is closer to the epitaxy than the first cutting line, the lower roughness of the second cutting line 0101 can be more conducive to protecting the luminous epitaxy. Or the distance between the burst points of the second cutting line 0102 is greater than that of the first cutting line 0101, which can be more conducive to protecting the luminous epitaxy.

### Embodiment 2

This embodiment also provides a flip-chip semiconductor light-emitting element. The similarities with the semiconductor light-emitting element provided in embodiment 1 will not be repeated. The differences are:

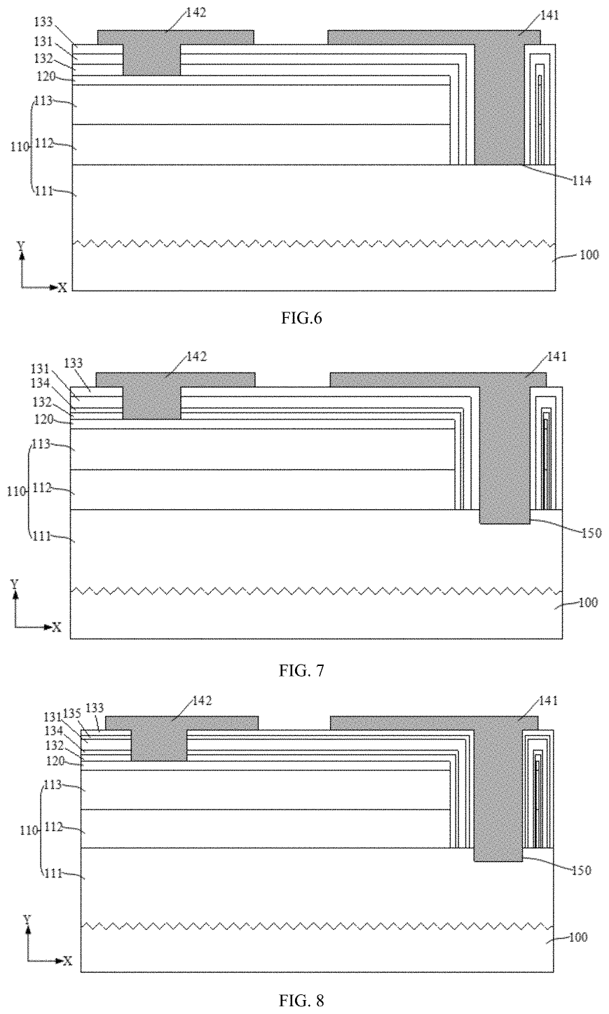

In this embodiment, as illustrated in FIG. 7, the insulating layer 130 further includes a third insulating protective layer 134, the third insulating protective layer 134 is disposed between the first insulating protective layer 132 and the insulating reflective layer 131, and the compactness of the third insulating protective layer 134 is higher than that of the insulating reflective layer 131, but lower than that of the first insulating protective layer 132. The first insulating protective layer 132 is obtained by atomic layer deposition (ALD), for example, the first insulating protective layer 132 is an aluminum oxide layer, and the third insulating protective layer 134 is obtained by PECVD, for example, the third insulating protective layer 134 is a silicon oxide layer. A thickness of the third insulating protective layer 134 is in a range of 80 nm to 450 nm. Preferably, the thickness of the first insulating protective layer 132 is lower than that of the third insulating protective layer 134, so as to form a gradient dense film layer, which can effectively protect against the invasion of water vapor. In addition, the first insulating protective layer 132 and the third insulating protective layer 134 are obtained by combining ALD process and PECVD process. From the perspective of process, the first insulating protective layer 132 can save process time than that obtained by a single process. From the perspective of compactness protection effect, the third insulating protective layer 134 have more effective than a single third insulating protective layer. Preferably, the thickness of the first insulating protective layer 132 is no greater than 200 nm, and a thickness ratio of the first insulating protective layer 132 to the third insulating protective layer 134 is in a range of 1:3 to 1:5.

### Embodiment 3

This embodiment provides a flip-chip semiconductor light-emitting element. The similarities with the semiconductor light-emitting element provided in embodiment 1 will not be repeated. The differences are:

As illustrated in FIG. 8, the insulating layer 130 in this embodiment further includes a fourth insulating protective layer 135, the fourth insulating protective layer 135 is disposed between the second insulating protective layer 133 and the insulating reflective layer 131, and the compactness of the fourth insulating protective layer 135 is higher than that of the insulating reflective layer 131 but lower than that of the second insulating protective layer 133. The second insulating layer 133 is obtained by the ALD process, for example, the second insulating layer 133 is aluminum oxide layer, and the fourth insulating protective layer 135 is obtained by the PECVD process, for example, the fourth insulating protective layer 135 is silicon oxide layer or silicon nitride layer. Preferably, a thickness of the second insulating protective layer 133 is in a range of 8 nm to 200 nm, and a thickness of the fourth insulating protective layer 135 is in a range of 8 nm to 50 nm.

### Embodiment 4

This embodiment provides a flip-chip semiconductor light-emitting element. The similarities with the semiconductor light-emitting element provided in embodiment 1 will not be repeated. The differences are:

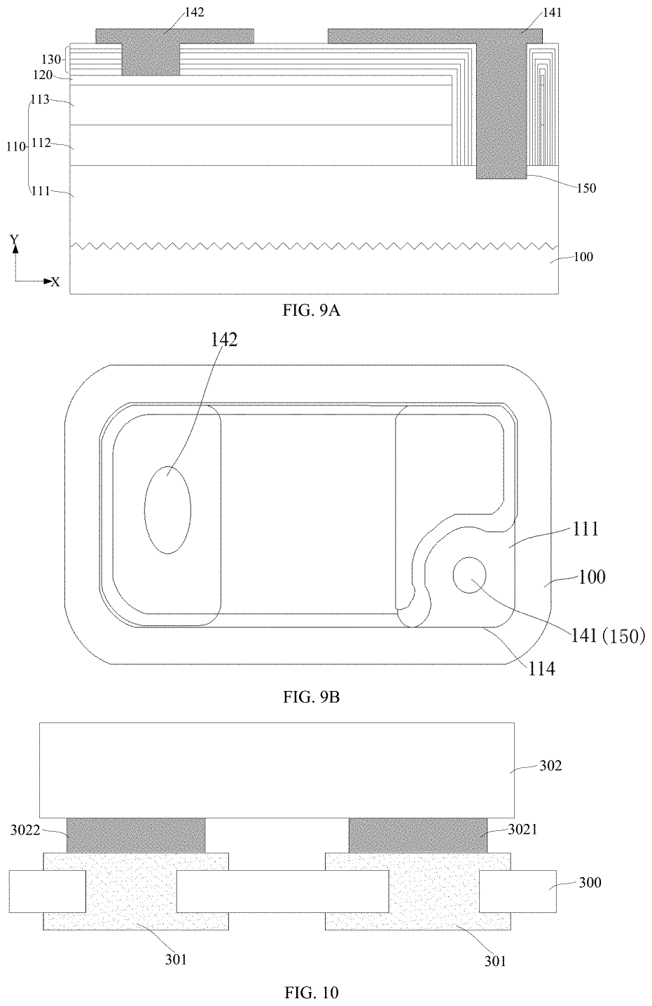

As illustrated in FIG. 9A and FIG. 9B, before the semiconductor light-emitting element of this embodiment forms with the first pad 141, the insulating layer 130 is etched while continuing to etch the first conductive type semiconductor layer 111. In the first conductive type semiconductor layer 111, more specifically, a recess 150 is formed in the mesa 114, and then the conductive material is deposited to form the first electrode pad 141. The first electrode pad 141 electrically contacts to the first conductive type semiconductor layer 111. The recess 150 increases a contact area between the first electrode pad 141 and the first conductive type semiconductor layer, which is conducive to reducing a voltage of the light-emitting element and improving the light-emitting efficiency. A direction of any surface of the upper and lower surfaces opposite to the active layer is the horizontal plane direction, and an area of the recess in the horizontal plane direction is less than an area of the mesa 114 in the horizontal plane direction, or as illustrated in FIG. 9B, the width of the recess in the horizontal plane direction is less than the width of the mesa 114 in the horizontal plane direction.

In an optional embodiment, in the X direction shown in FIG. 9B, a width of an upper opening of the recess is greater than a width of a bottom opening of the recess, the width of the bottom opening of the recess is in a range of 4 μm to 12 μm, and a depth of the recess in the Y direction is in a range of 20 nm to 100 nm. The side wall of the recess is not vertically linear with respect to the upper surface of the first conductive type semiconductor layer, for example, it is a relatively inclined linear type, arc type or curve type. In the Y direction shown in FIG. 9B, the width of the recess in the X direction gradually increases from bottom to top, and the recess shape becomes an inverted trapezoidal structure with a longitudinal section shape. The recess with the above characteristics forms a gentle slope in the depth direction, which is conducive to the coverage of the subsequently deposited electrode material, so that the electrode material will not have cracks or fractures, and the reliability of the light-emitting element can be further improved.

### Embodiment 5

This embodiment provides a semiconductor light-emitting device, as illustrated in FIG. 10, the light-emitting device includes a package bracket 300 and a semiconductor light-emitting element 302 fixed to the package bracket 300. The packaging bracket 300 may be an insulating bracket. As illustrated in FIG. 10, the package bracket 300 is provided with pad structures 301, which are connected to the electrode pads 3021 and 3022 of the semiconductor light-emitting element respectively.

The semiconductor light-emitting element 302 in this embodiment can be the semiconductor light-emitting element provided in one of embodiment 1 to embodiment 4. The specific structure can refer to the descriptions of embodiment 1 to embodiment 4, and will not be repeated here.

The semiconductor light-emitting device of this embodiment includes the semiconductor light-emitting element provided in one of embodiment 1 to embodiment 4, so it has good reliability and light output efficiency.

### Embodiment 5

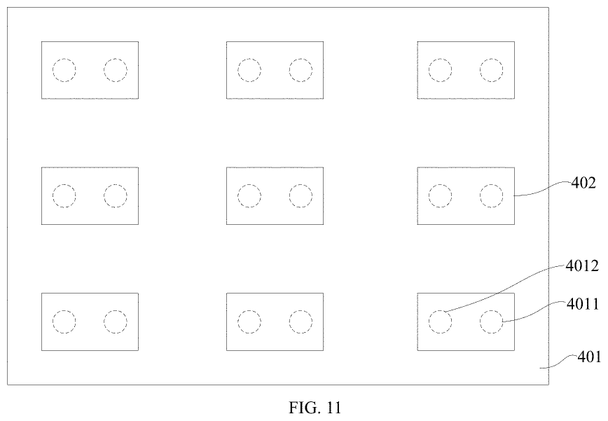

This embodiment provides a display device, as illustrated in FIG. 11, the display device includes a circuit substrate 401 and a plurality of semiconductor light-emitting elements electrically connected to the circuit substrate. In this embodiment, the semiconductor light-emitting element 402 is the semiconductor light-emitting element provided in one of embodiment 1 to embodiment 4. As illustrated in FIG. 11, the circuit substrate 401 has a plurality of groups of pads, each group of pads includes a first pad 4011 and a second pad 4012, and the first electrode pad and the second electrode pad of the semiconductor light-emitting element 402 are electrically connected to the first pad 4011 and the second pad 4012 respectively. For example, the first electrode pad and the second electrode pad of the semiconductor light-emitting element 100 may be bonded to the first pad 4011 and the second pad 4012 by conductive adhesive. In the FIG. 11, a plurality of semiconductor light-emitting elements are arranged in a matrix on the circuit substrate. It can be understood that the semiconductor light-emitting elements 100 can be arranged on the circuit substrate in any suitable manner according to the actual display needs. The display device may be an RGB display panel in which a plurality of semiconductor light-emitting elements are a combination of blue, red and green semiconductor light-emitting elements. The semiconductor light-emitting element of the disclosure can be at least one of the blue semiconductor light-emitting element, the green semiconductor light-emitting element and the red semiconductor light-emitting element.

As described above, the semiconductor light-emitting element, the semiconductor light-emitting device and the display device provided by the disclosure have at least the following beneficial technical effects:

the flip-chip semiconductor light-emitting element of the disclosure includes a substrate and the light-emitting epitaxial layer disposed on the substrate, when electrode structures is formed overlying the light-emitting epitaxial layer, a first electrode layer partially covering the light-emitting epitaxial layer and on the light-emitting epitaxial layer is omitted, thus a surface of the light-emitting epitaxial layer has a high flatness. When an insulating reflective layer and an insulating protective layer are subsequently formed, flatness of the insulating reflective layer and the insulating protective layer can be ensured. Moreover, in the disclosure, an overall thickness of the insulating reflective layer and the insulating protective layer is no greater than 3 μm, when electrode through holes are formed in the insulating reflective layer and the insulating protective layer, abnormal protrusions will not occur due to the excessive thickness of the insulation protective layer, the electrode through holes have good morphology, and the adhesion of the electrode pads in the electrode through holes and on the insulating protective layer is enhanced, the electrode pads will not have defects such as cracks or fractures, thereby the stability and reliability of the device can be enhanced. In addition, in the prior art, the thickness of the insulating layer is too thick, in order to ensure a size of a bottom opening of the electrode through hole of the insulating reflective layer, an upper opening of the electrode through hole is too large, which may lead to a risk of electric leakage due to the portion of the insulating reflective layer near the side wall of the mesa is thin, or a risk of reduction of luminous area due to the mesa is too large, the disclosure can avoid the above risks.

In addition, since the thickness of the insulating reflective layer and the insulating protective layer of the disclosure is controlled to be no more than 3 μm as a whole, when the electrode through hole is formed, the size of the electrode through hole, especially the n-electrode through hole, can be controlled to reduce, and the distance between the n-electrode through hole and the edge of the mesa of the light emitting epitaxial layer can be reduced, so that the area of the n-type layer can be reduced and the area of the p-type layer can be increased. Further, the mesa can be made at the edge of the light-emitting epitaxial layer, and the n-type electrode through hole can be made into a circular through hole, so as to further reduce the area of the n-type layer and increase the area of the p-type layer. Thus, the light-emitting area of the semiconductor light-emitting element is correspondingly increased, and the light output efficiency of the light-emitting element is improved. Secondly, because the current expansion of the p-type layer is worse than that of the n-type layer, when the area of the n-type layer decreases and the area of the p-type layer increases, the current expansion of the n-type layer and the p-type layer can be balanced, so as to improve the ESD capability of the semiconductor light-emitting elements.

In another embodiment of the disclosure, when the insulating reflective layer and the insulating protective layer are etched to form an n-type electrode through hole, the n-type semiconductor layer can be further etched to form a recess structure in the n-type semiconductor layer. The recess structure increases the contact area between the electrode pad and the semiconductor layer, which is conducive to reducing the working voltage of the semiconductor light-emitting element and improving its luminous efficiency. Further, the top width of the recess structure is greater than the bottom width, a gentle slope is formed in the depth direction of the recess structure. The gentle slope is beneficial to increase the contact area between the subsequently deposited electrode material and the n-type semiconductor layer, reduce the voltage, prevent the electrode material from cracking or fracture, and further improve the reliability of the light-emitting element.

What is claimed is:

1. A flip-chip semiconductor light-emitting element, comprising:
a light-emitting epitaxial layer, comprising: a first conductive type semiconductor layer, an active layer, and a second conductive type semiconductor layer sequentially stacked from bottom to top in that order, wherein the light-emitting epitaxial layer is provided with a mesa, and the first conductive type semiconductor layer forms an upper surface of the mesa;
an insulating layer comprising an insulating reflective layer, disposed overlying the light-emitting epitaxial layer and covering side walls of the light-emitting epitaxial layer on two sides of the mesa; and
electrode pads, comprising: a first electrode pad electrically connected to the first conductive type semiconductor layer, and a second electrode pad electrically connected to the second conductive type semiconductor layer;
wherein a thickness of the insulating reflective layer is in a range of 1 μm to 3 μm.

2. The flip-chip semiconductor light-emitting element according to claim 1, wherein the insulating layer further comprises:
a first insulating protective layer, disposed between the insulating reflective layer and the second conductive type semiconductor layer.

3. The flip-chip semiconductor light-emitting element according to claim 2, wherein the insulating layer further comprises: a second insulating protective layer, disposed overlying the insulating reflective layer;
wherein a thickness of the second insulating protective layer is less than a thickness of each of insulating material layers in the insulating reflective layer.

4. The flip-chip semiconductor light-emitting element according to claim 3, wherein the second insulating protective layer is one of an aluminum oxide layer with a thickness in a range of 8 nm to 200 nm, and a silicon oxide layer with a thickness in a range of 8 nm to 50 nm.

5. The flip-chip semiconductor light-emitting element according to claim 2, wherein the insulating layer further comprises:
a third insulating protective layer, disposed between the first insulating protective layer and the insulating reflective layer;
wherein the first insulating protective layer is an aluminum oxide layer, and the third insulating protective layer is a silicon oxide layer;
wherein a thickness of the first insulating protective layer is less than a thickness of the third insulating protective layer.

6. The flip-chip semiconductor light-emitting element according to claim 5,
wherein the first insulating protective layer is the aluminum oxide layer with a thickness in a range of 50 nm to 200 nm, and the third insulating protective layer is the silicon oxide layer with a thickness in a range of 80 nm to 450 nm.

7. The flip-chip semiconductor light-emitting element according to claim 6, wherein a ratio of the thickness of the first insulating protective layer to the thickness of the third insulating protective layer is in a range of 1:3 to 1:5.

8. The flip-chip semiconductor light-emitting element according to claim 3, wherein the insulating layer further comprises: a fourth insulating protective layer, disposed between the second insulating protective layer and the insulating reflective layer;
wherein the second insulating protective layer is an aluminum oxide layer with a thickness in a range of 8 nm to 200 nm.

9. The flip-chip semiconductor light-emitting element according to claim 8, wherein the fourth insulating protective layer is a silicon oxide layer with a thickness in a range of 8 nm to 50 nm.

10. The flip-chip semiconductor light-emitting element according to claim 2, wherein the insulating layer is defined with a first through hole and a second through hole, the first through hole penetrates through the insulating layer corresponding to the mesa to expose the first conductive type semiconductor layer at the mesa, and the second through hole penetrates through the insulating layer corresponding to the second conductive type semiconductor layer to expose the second conductive type semiconductor layer; and
wherein the first electrode pad is formed in the first through hole, the second electrode pad is formed in the second through hole, and the first through hole is a circular through hole.

11. The flip-chip semiconductor light-emitting element according to claim 10, wherein a recess is defined in the first conductive type semiconductor layer at the mesa and below the first through hole in the insulating layer.

12. The flip-chip semiconductor light-emitting element according to claim 11, wherein a width of an upper opening of the recess is less than a width of the mesa.

13. The flip-chip semiconductor light-emitting element according to claim 12, wherein the first electrode pad electrically contacts to the first conductive type semiconductor layer, and the width of the upper opening of the recess is greater than a width of a bottom opening of the recess.

14. The flip-chip semiconductor light-emitting element according to claim 13, wherein a depth of the recess is greater than or equal to 20 nm and is less than or equal to 100 nm, and the width of the bottom opening of the recess is in a range of 4 μm to 12 μm.

15. The flip-chip semiconductor light-emitting element according to claim 2, wherein at least one dimension of the flip-chip semiconductor light-emitting element is no greater than 300 μm.

16. The flip-chip semiconductor light-emitting element according to claim 2, wherein the flip-chip semiconductor light-emitting element further comprises a substrate, the light-emitting epitaxial layer is disposed on the substrate, a thickness of the substrate is no greater than 100 and a side wall of the substrate is defined with at least two cutting lines of different depths.

17. The flip-chip semiconductor light-emitting element according to claim 16, wherein a number of the at least two cutting lines is two, a first cutting line of the two cutting lines is closer to a position corresponding to ½ of the thickness of the substrate than a second cutting line of the two cutting lines, and the second cutting line is closer to the light-emitting epitaxial layer than the first cutting line.

18. The flip-chip semiconductor light-emitting element according to claim 16,
wherein a number of the at least two cutting lines is two; and
wherein a roughness of a first cutting line of the two cutting lines is higher than that of a second cutting line of the two cutting lines, or a burst point spacing of the first cutting line is smaller than that of the second cutting line.

19. A semiconductor light-emitting device, comprising:
a circuit substrate; and
a semiconductor light-emitting element, flip-chip mounted on the circuit substrate, wherein the semiconductor light-emitting element is the flip-chip semiconductor light-emitting element according to claim 1.
